(19) United States
(12) Patent Application Publication
(10) Pub. No.: US 2008/0096303 A1
(43) Pub. Date: Apr. 24, 2008

(54) FABRICATION METHOD OF IMAGE SENSING DEVICE

(75) Inventor: Ming-I Wang, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: UNITED MICROELECTRONICS CORP., Hsinchu (TW)

(21) Appl. No.: 11/963,852

(22) Filed: Dec. 24, 2007

Related U.S. Application Data
(62) Division of application No. 11/308,620, filed on Apr. 13, 2006.

(51) Int. Cl. H01L 31/18

(52) U.S. Cl. 438/70; 257/E31.127

(57) ABSTRACT

An image sensing device includes a substrate with a photo sensing and a transistor regions, a photo diode, a transistor, a dielectric layer, a metal interconnect, a metal conductive line, a conformal passivation layer, a color filter, a lens planar layer, and a microlens. The photo diode is in the substrate within the photo sensing region. The transistor is on the substrate in the transistor region. The dielectric layer is on the substrate. Except the photo sensing region, the metal interconnect and the metal conductive line are respectively located in and on the dielectric layer. The conformal passivation layer is on the dielectric layer and covers the metal conductive line. The color filter is on the conformal passivation layer in the photo sensing region and the bottom thereof is lower than the top of the metal conductive line. The lens planar layer and the microlens are sequentially on precedent structure.

### CROSS-REFERENCE TO RELATED APPLICATION

This application is a divisional of an application Ser. No. 11/308,620, filed on Apr. 13, 2006, now pending. The entirety of each of the above-mentioned patent applications is hereby incorporated by reference herein and made a part of this specification.

### BACKGROUND OF THE INVENTION

1. Field of the Invention

The present invention relates to a sensing device and a fabrication method thereof. More particularly, the present invention relates to an image sensing device and a fabrication method thereof.

2. Description of Related Art

At present, the photodiode image sensor is a common image sensing device. A typical photodiode image sensor comprises a transistor and a photo diode. For a photo diode formed by an N-type doped region and a P-type substrate (n+/p) acting as a photo sensing region, during the operation of a photodiode image sensor, a voltage is applied to the gate of the transistor to turn on the transistor and then charge the junction capacitor of the n+/p photo diode. When the voltage reaches a high voltage level, the transistor is turned off, making the n+/p photo diode generate a reversed bias forming a depletion region. When the n+/p photodiode photosensitive region is exposed to light, the electron hole pair generated may be separated by the electric field of the depletion region, thus the electrons move toward the N-type doped region, thereby reducing the voltage level of the N-type doped region, and the electron holes flow toward the P-type substrate. If the N-type doped region is connected to a source follower formed by a transfer transistor, the output end can be quickly charged and discharged with the high current provided by the source follower, for stabilizing the voltage at output end and keeping noise low. Such a photo sensor is an active-pixel photodiode sensor.

Recently, in the application of many low-cost image sensors, active-pixel photodiode complimentary metal oxide semiconductor image sensor has become a substitute for charge coupled device (CCD). The active-pixel photodiode complimentary metal oxide semiconductor image sensor is characterized by high quantum efficiency, low read noise, high dynamic range, and random access etc., and it is completely compatible with the process of complimentary metal oxide semiconductor (CMOS) element, so it is very easy to be integrated with other elements on the same chip to obtain a so-called system on a chip (SOC). Therefore, the active-pixel photodiode CMOS image sensor is a trend for the future development of image sensors.

FIG. 1 is a sectional view of the structure of a conventional active-pixel photodiode CMOS image sensor. Referring to FIG. 1, the substrate 100 is divided into a photo sensing region 102 and a transistor region 104. The substrate 100 has an isolation structure 106 to isolate different elements in the substrate 100. The substrate 100 within the photo sensing region 102 has a photo diode 110, while the substrate 100 of the transistor region 104 has a transistor 120. The transistor 120 includes a dielectric layer 122, a gate conductor layer 124 and a source/drain region 126. The substrate 100 has multiple dielectric layers 130 and a metal interconnect 132 thereon, in which the metal interconnect 136 is formed by connecting conductor plugs 134 and metal conductive lines 136. A passivation layer 140 formed by depositing and then performing a chemical mechanical polishing (CMP) process is disposed on the top dielectric layer 130 and utilized to protect underlying structure and reducing the light reflection. A color filter 150 lies on the passivation layer 140. In the device, there are often three or more color filters 150 arranged to be a color filter array. The color filters only allow visible light of a certain frequency to pass through to reach the corresponding image sensor. A lens planar layer 160 lies on the color filter 150 and a microlens 170 is disposed on the lens planar layer 160.

It should be noted that as the light (the down arrow in FIG. 1) path to the photo diode 110 of the above device is too long, the microlens 170 cannot effectively focus the light on the photo diode 110, resulting in a reduction in the sensitivity of the photodiode CMOS image sensor to light and causing a cross talk after integrating other elements. Therefore, a process is developed to treat the passivation layer 140 through a chemo-mechanical polish before forming the color filter 150 so as to reduce the thickness and shortening the light path. However, the process is very complicated and it is highly desirable to improve the sensitivity of the sensor to light without affecting its preset performance.

### SUMMARY OF THE INVENTION

The object of the invention is to provide an image sensing device and a fabrication method thereof, wherein the length of the light path is reduced and the alignment of the color filter can be enhanced so that the sensitivity of the image sensing device to light can be effectively enhanced.

The image sensing device of the invention includes a substrate with a photo sensing region and a transistor region, a photo diode, a transistor, a dielectric layer, a metal interconnect, a metal conductive line, a conformal passivation layer, a color filter, a lens planar layer and a microlens. The photo diode is disposed in the substrate within the photo sensing region. The transistor is disposed on the substrate in the transistor region. The dielectric layer is disposed on the substrate. Except within the photo sensing region, the metal interconnect and the metal conductive line are respectively disposed in and on the dielectric layer. The conformal passivation layer is disposed on the dielectric layer and covers the metal conductive line. The color filter is disposed on the conformal passivation layer in the photo sensing region and the bottom thereof is lower than the top of the metal conductive line. The lens planar layer and the microlens are sequentially disposed on the precedent structure.

According to one embodiment of the invention, in the aforementioned image sensing device, the conformal passivation layer includes a SiO layer, a SiN layer, a SiON layer, or a lamination thereof.

According to one embodiment of the invention, in the above-mentioned image sensing device, a part of the color filter can be overlapped with a part of the metal conductive line.

According to one embodiment of the invention, in the above-mentioned image sensing device, the bottom surface of the metal conductive line is higher than the bottom surface of the color filter.

According to one embodiment of the invention, in the above-mentioned image sensing device, an anti-reflective coating is further included between the substrate and the dielectric layer. The material for the anti-reflective coating includes SiN.

According to one embodiment of the invention, in the above-mentioned image sensing device, the transistor includes a gate dielectric layer on the substrate, a gate conductor layer on the gate dielectric layer and a source/drain region in the substrate at both sides of the gate conductor layer.

According to one embodiment of the invention, in the above-mentioned image sensing device, the dielectric layer includes a lamination having a phosphosilicate glass layer formed by using tetra-ethyl-ortho-silicate as a reactive gas source, an undoped silicate glass layer, a material layer formed by using tetra-ethyl-ortho-silicate as the reactive gas source and a material layer formed through high density plasma (HDP) (i.e. a HDP material layer).

According to one embodiment of the invention, in the above-mentioned image sensing device, the metal conductive line includes aluminum, copper or tungsten. The lens planar layer includes a transparent polymeric material. The microlens includes a photoresist material of high transmittance.

The invention provides a method for fabricating the image sensing device. First, a photo diode is formed in the photo sensing region of the substrate. Then, a transistor electrically connected to the photo diode is formed on the transistor region of the substrate. Next, an interconnect structure is formed on the substrate, and the interconnect structure includes a dielectric layer and multiple layers of metal interconnects, wherein the metal interconnects are located in the dielectric layer except the photo sensing region. A metal material layer is formed on the dielectric layer. The metal material layer is patterned to form a metal conductive line outside the photo sensing region and to form an opening in the photo sensing region. Then, a conformal passivation layer is formed on the dielectric layer covering the metal conductive line. The opening is filled with a color filter. A lens planar layer is formed on the color filter and the conformal passivation layer. After that, a microlens is formed on the lens planar layer in the photo sensing region.

According to one embodiment of the invention, in the aforementioned method for fabricating an image sensing device, the step of patterning the metal material layer further includes removing a portion of the dielectric layer from the photo sensing region.

According to one embodiment of the invention, in the aforementioned method for fabricating an image sensing device, the conformal passivation layer includes a SiO layer, a SiN layer, a SiON layer, or a lamination thereof. The step of fabricating the conformal passivation layer includes performing a chemical vapor deposition.

According to one embodiment of the invention, in the aforementioned method for fabricating an image sensing device, an anti-reflective coating is further formed on the substrate covering the transistor and the photo diode before the interconnect structure is formed on the substrate.

According to one embodiment of the invention, in the aforementioned method for fabricating an image sensing device, the dielectric layer includes a lamination having a phosphosilicate glass layer formed by using tetra-ethyl-ortho-silicate as the reactive gas source, an undoped silicate glass layer, a material layer formed by using tetra-ethyl-ortho-silicate as the reactive gas source, and a material layer formed through high density plasma.

In the method for fabricating an image sensing device according to the invention, a thin conformal passivation layer is formed, and therefore a chemical mechanical polishing (CMP) process for planarizing the conventional passivation layer can be saved. Moreover, the conformal passivation layer according to the invention has the same function as a anti-reflective coating. Therefore, the process can be simplified, the incident light path can be shortened so the light can precisely enter the photo diode. Thus, the sensitivity of the image sensing device to light can be enhanced and the interference between the lines can be reduced. Moreover, the color filter can be precisely formed on the photo diode in the photo sensing region, which would reduce the difficulty of aligning the color filter with the photo diode and thereby improving the process tolerance.

In order to the make the aforementioned and other objects, features and advantages of the present invention comprehensible, a preferred embodiment accompanied with figures is described in detail below.

### BRIEF DESCRIPTION OF THE DRAWINGS

FIG. 1 is a schematic sectional view of the structure of a conventional image sensing device.

FIG. 2 is a schematic sectional view of the structure of the image sensing device according to one embodiment of the invention.

FIG. 3 is a schematic sectional view of the image sensing device according to another embodiment of the invention.

FIGS. 4A to 4E are schematic sectional views of the flow of the method for fabricating the image sensing device according to one embodiment of the invention.

FIGS. 4F to 4H are schematic sectional views of the flow of the method for fabricating the image sensing device according to another embodiment of the invention.

### DESCRIPTION OF EMBODIMENTS

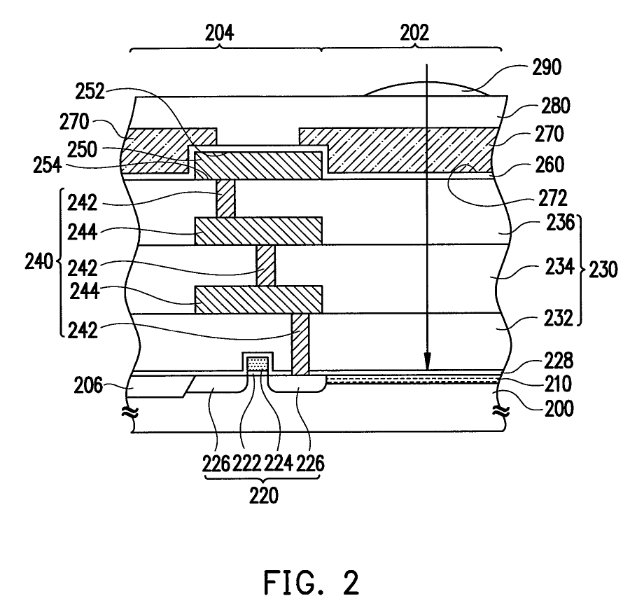

FIG. 2 is a schematic sectional view of the structure of the image sensing device according to one embodiment of the invention.

Referring to FIG. 2, the image sensing device of the invention includes a substrate 200, a photo diode 210, a transistor 220, a dielectric layer 230, a metal interconnect 240, a metal conductive line 250, a conformal passivation layer 260, a color filter 270, a lens planar layer 280 and a microlens 290.

The substrate 200 has a photo sensing region 202 and a transistor region 204. Usually, an isolation structure 206 is formed in the substrate 200 for electrically isolating various elements in the substrate 200. The photo diode 210 is disposed in the photo sensing region 202 of the substrate 200, and the transistor 220 is disposed on the transistor region 204 of the substrate 200. The transistor 220 includes a gate dielectric layer 222, a gate conductor layer 224 and a source/drain region 226. The aforementioned photo diode 210 is electrically connected to the transistor 220, i.e., the photo diode 210 is connected to the source/drain region 226. The above-mentioned transistor 220 can be a reset transistor, an output selecting transistor, a transfer transistor or the like. The image sensing device comprises, for example, photodiode CMOS image sensor. Moreover, if the substrate 200 is N-type, the photo diode 210 is P-type. On the other hand, if the substrate 200 is P-type, the photo diode 210 is N-type.

The dielectric layer 230 is disposed on the substrate 200 covering the transistor 220 and the photo diode 210. The dielectric layer 230 comprises, for example, an inter-layer dielectric layer or an inter-metal dielectric layer, wherein the number of the layers and arrangement are designed according to the requirement. The dielectric layer 230 is comprised of, for example, a combined lamination of a phosphosilicate glass layer formed by using tetra-ethyl-ortho-silicate as the reactive gas source, an undoped silicate glass layer, a material layer formed by using tetra-ethyl-ortho-silicate as the reactive gas source and a material layer formed through high density plasma.

In one embodiment, the dielectric layer 230, for example, includes an inter-layer dielectric layer 232 and inter-metal dielectric layers 234, 236. The inter-layer dielectric layer 232 is, for example, formed by first forming an undoped silicate glass, and then forming a layer of phosphosilicate glass by using tetra-ethyl-ortho-silicate as the reactive gas source. The inter-metal dielectric layers 234, 236 are, for example, formed by first forming a rigid material layer through high density plasma and then forming a soft material layer by using tetra-ethyl-ortho-silicate as the reactive gas source.

Moreover, an anti-reflective coating 228 is further included between the substrate 200 and the dielectric layer 230 covering the transistor 220 and the photo diode 210. The anti-reflective coating 228 is adopted for substantially prevent the incident light received in the photodiode region 210 from being reflected. The anti-reflective coating 228 comprises, for example, SiN or other suitable materials.

The metal interconnect 240 is disposed in the dielectric layer 230 except in the photo sensing region 202, and is electrically connected to the transistor 220. The metal interconnect 240, for example, includes multiple conductor plugs 242 and multiple metal conductive lines 244. The number of the layers of the conductor plugs 242 and the metal conductive lines 244 are determined by the number of the dielectric layer 230. The adjacent conductor plug 242 and metal conductive line 244 are electrically connected to the top dielectric layer 230 by the transistor 220. The metal conductive line 250 is disposed on the dielectric layer 230 except the photo sensing region 202, and is connected to the top of the metal interconnect 240. The metal conductive lines 244, 250 comprise, for example, aluminum, copper, tungsten, or another suitable metal. The conductor plugs 242 may be comprised of, for example, aluminum, copper, tungsten, or other suitable conductive material.

Of course, the image sensing device depicted in FIG. 2 is illustrated by the dielectric layer 230 with three layers and the metal interconnect 240, however it is not limited such a structure, any number of the layers of the metal interconnect 240 and the dielectric layer 230 can be used in accordance with the circuit design or the process.

The conformal passivation layer 260 is disposed on the dielectric layer 230 covering the metal conductive line 250. The conformal passivation layer 260 comprises, for example, a SiO layer, a SiN layer, a SiON layer, or a lamination thereof. The color filter 270 is disposed on the conformal passivation layer 260 in the photo sensing region 202, and the bottom surface 272 of the color filter 270 is lower than the top surface 252 of the metal conductive line 250. Often, more than one color filter 270 is provided in the device to form a color filter array. The lens planar layer 280 is disposed on the color filter 270 and on a part of the conformal passivation layer 260, wherein the lens planar layer 280 comprises, for example, transparent polymeric material or other suitable materials. The microlens 290 is disposed on the lens planar layer 280 in the photo sensing region 202, wherein the microlens 290 comprises, for example, a photoresist material with a high transmittance.

In the embodiment, as the bottom surface 272 of the color filter 270 and the bottom surface 254 of the metal conductive line 250 are near the same plane, a part of the color filter 270 is overlapped with a part of the metal conductive line 250.

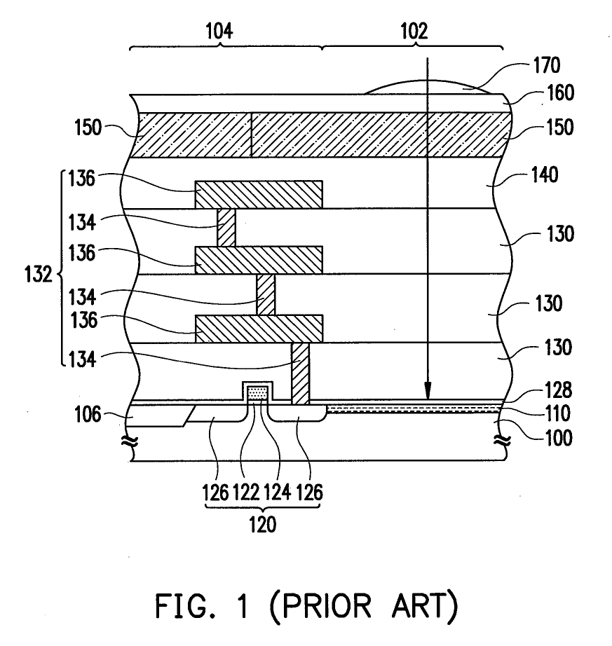

In the aforementioned structure of the image sensing device, the conformal passivation layer 260 is formed depending on the change of the surface profiles of the dielectric layer 230 and the metal conductive line 250, and thus it is different from the conventional passivation layer (refer to the passivation layer 140 in FIG. 1). Although the conformal passivation layer 260 is thinner than a conventional one, it can be a lamination composed of material layers having different functions. Therefore, the functions of a conventional passivation layer still can be maintained; for example, when the conformal passivation layer 260 comprises a SiN layer or a SiON layer, it has the function of anti-reflection due to the material the same as a anti-reflective coating. As such, the incident light path is shortened, and the color filter 270 is directly disposed at both sides of the metal conductive line 250 and precisely disposed above the photo diode 210 of the photo sensing region 202, so the incident light can precisely enter the photo diode 210. Thus, the sensitivity of the image sensing device to light is enhanced and the interference between different elements is reduced. Furthermore, the manufacture process can be simplified because of saving the CMP in the formation of the conformal passivation layer 260.

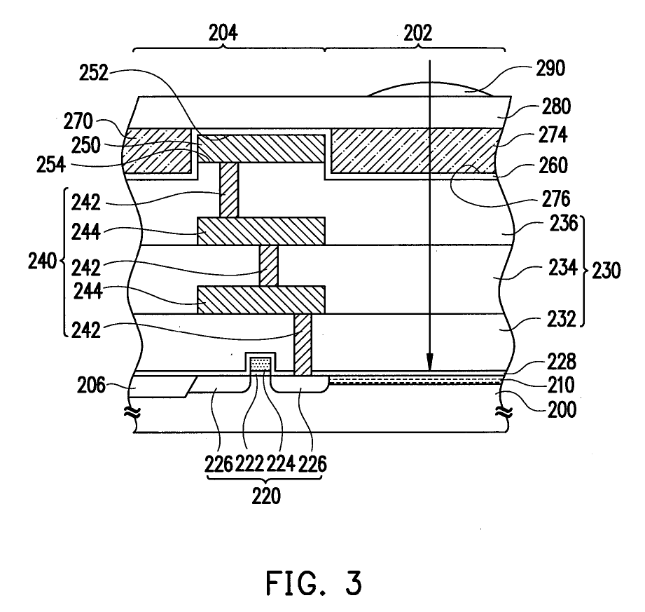

FIG. 3 is a schematic sectional view of the structure of the image sensing device according to another embodiment of the invention which is similar to the embodiment of FIG. 2 except for the bottom surface 276 of the color filter 274 is, for example, lower than the bottom surface 254 of the metal conductive line 250, i.e., the color filter 274 and the metal conductive line 250 may or may not have an overlapped portion.

In the structure of the image sensing device according to the embodiment, the color filter 274 is precisely located above the photo diode 210 of the photo sensing region 202. The conformal passivation layer 260 and the dielectric layer 230 is thinner than a conventional one. Thus, the incident light path is short enabling the incident light to precisely enter the photo diode 210, thereby enhancing the sensitivity of the image sensing device to light and alleviating the interference between different elements.

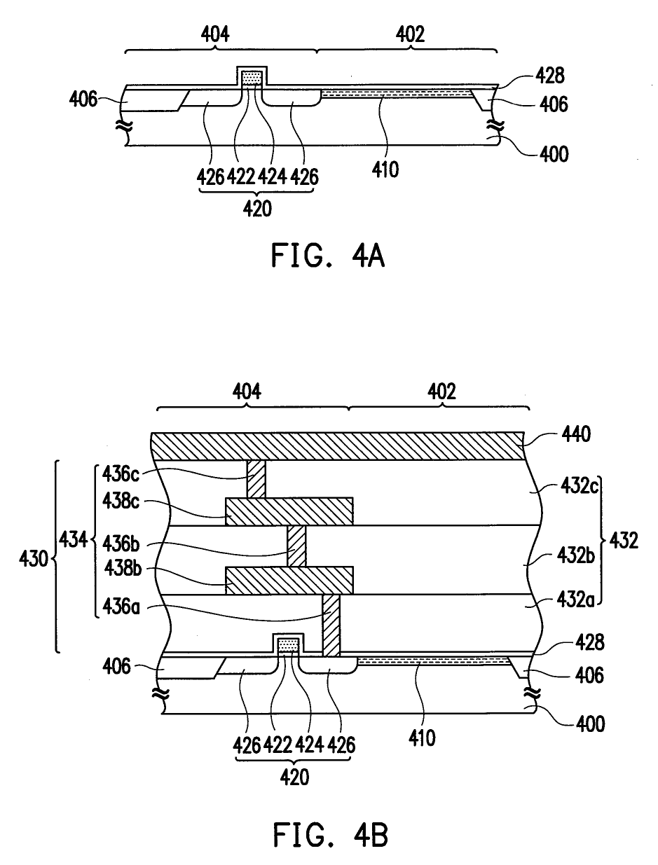

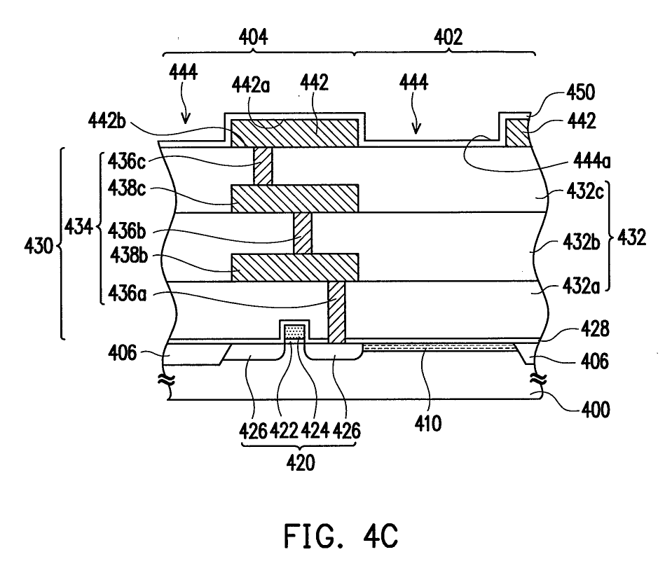

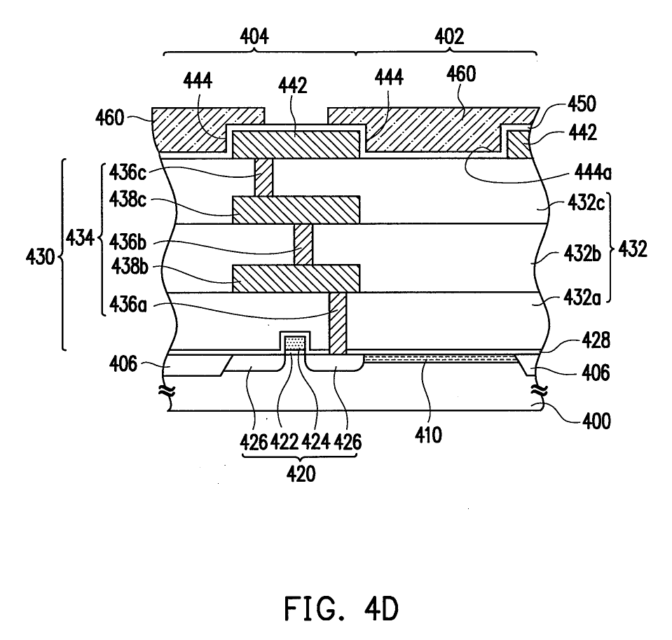

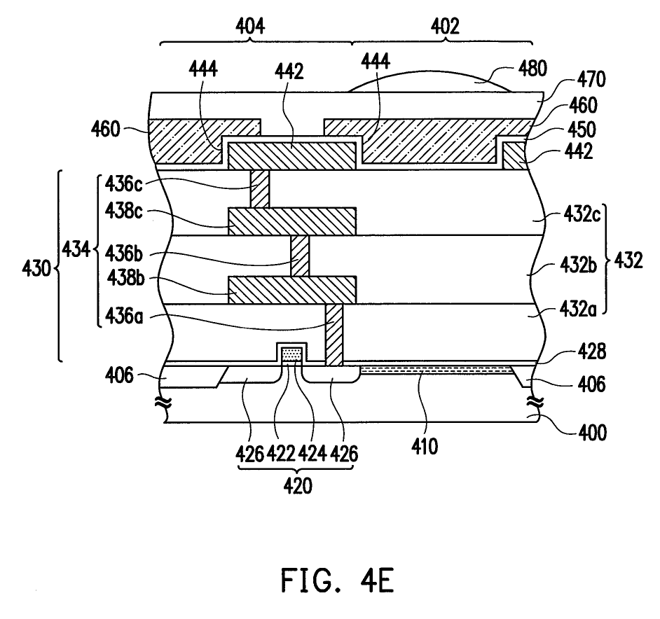

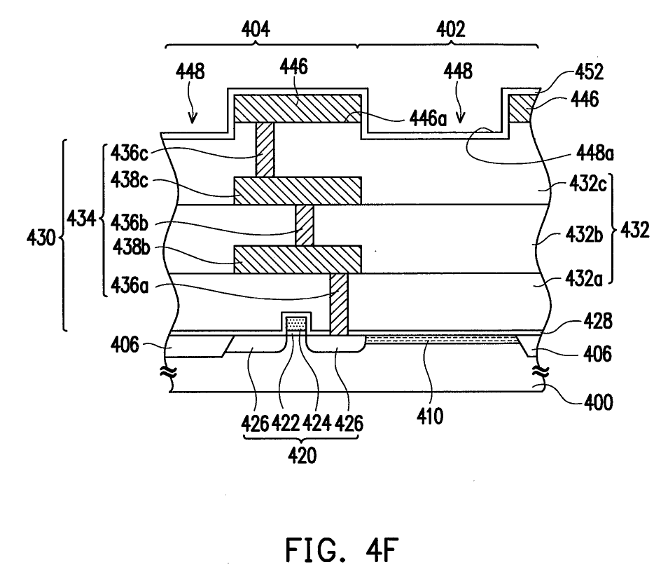

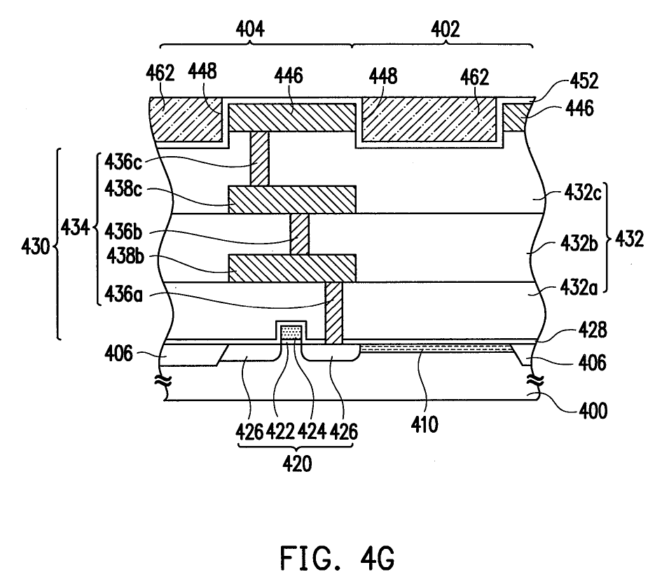

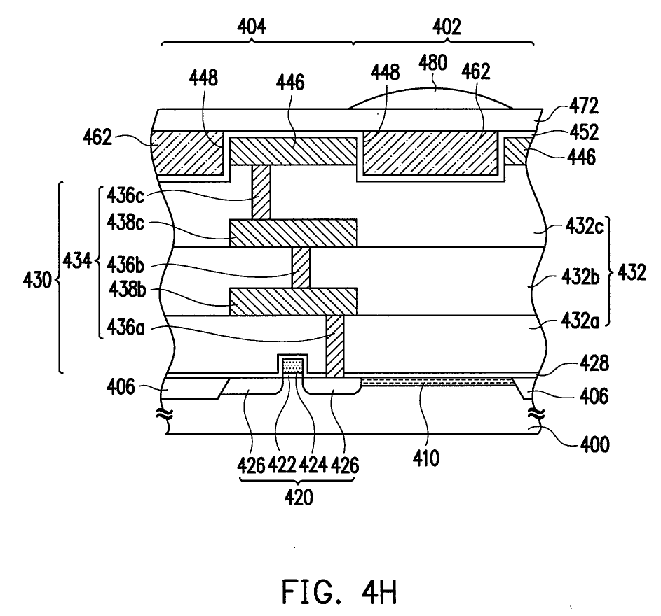

FIGS. 4A to 4E are schematic sectional views of the flow of the method for fabricating the image sensing device according to one embodiment of the invention.

First, referring to FIG. 4A, a photo diode 410 is formed in the photo sensing region 402 of the substrate 400. A transistor 420 is formed on the transistor region 404 of the substrate 400 having an isolation structure 406 formed thereon. The transistor 420 is electrically connected to the photo diode 410, and the transistor 420 includes a gate dielectric layer 422, a gate conductor layer 424 and a source/drain region 426. Then, an anti-reflective coating 428 is formed on the substrate 400, wherein the anti-reflective coating 428 comprises, for example, a SiN layer. The anti-reflective coating 428 covers the transistor 420 and the photo diode 410 for substantially preventing the incident light from being reflected and thereby reducing the incident light into the photo diode 410.

Then referring to FIG. 4B, an interconnect structure 430 is formed on the substrate 400, and includes a dielectric layer 432 and multiple layers of metal interconnects 434. The multiple layers of metal interconnects 434 have conductor plugs 436a, 436b and 436c and metal conductive lines 438a, 438b and 438c, and are positioned in the dielectric layer 432 except the photo sensing region 402. The dielectric layer 432 is, for example, an inter-layer dielectric layer 432a or an inter-metal dielectric layer 432b or 432c, and the number and arrangement thereof is designed in accordance with the requirement. The number of the layers of the conductor plugs 436 and the metal conductive lines 438 is determined by the number of the dielectric layer 432. The adjacent two conductor plugs 436a, 436b and 436c and metal conductive lines 438 a, 438b and 438c are electrically connected to the top dielectric layer 432 by the transistor 420. The dielectric layer 432 is, for example, a combined lamination of a phosphosilicate glass layer formed by using tetra-ethyl-ortho-silicate as the reactive gas source, an undoped silicate glass layer, a material layer formed by using tetra-ethyl-ortho-silicate as the reactive gas source, and a material layer formed through high density plasma. The metal conductive line 438a, 438b and 438c may be comprised of, for example, aluminum, copper, tungsten, or other suitable metal, while the conductor plugs 436a, 436b and 436c may be comprised of, for example, aluminum, copper, tungsten, or other suitable conductive material.

In one embodiment, first an inter-layer dielectric layer 432a is formed on the anti-reflective coating 428, wherein the inter-layer dielectric layer 432a comprises undoped silicate glass layer and then a phosphosilicate glass layer is formed by using tetra-ethyl-ortho-silicate as the reactive gas source. Thereafter, a conductor plug 436a is formed in the inter-layer dielectric layer 432a electrically connecting the source/drain region 426. A metal conductive line 438b is electrically connected to the conductor plug 436a on the inter-layer dielectric layer 432a. Next, an inter-metal dielectric layer 432b is formed on the inter-layer dielectric layer 432a by, for example, forming a rigid material layer through high density plasma and then forming a soft material layer by using tetra-ethyl-ortho-silicate as the reactive gas source. Likewise, a conductor plug 436b, a metal conductive line 438c, an inter-metal dielectric layer 432c and a conductor plug 436c are formed.

Of course, the aforementioned embodiment is illustrated by the interconnect structure 430 having three dielectric layer 432 layers and the multiple layers of metal interconnects 434, however any number of layers of metal interconnects 434 and the dielectric layer 432 can be used in accordance with the circuit design and the process.

Referring to FIG. 4B, a metal material layer 440 is formed on the dielectric layer 432. The metal material layer 440 comprises, for example, aluminum, copper, tungsten, or other suitable metals.

Next, referring to FIG. 4C, the metal material layer 440 is patterned to form a metal conductive line 442 outside the photo sensing region 402, and to form an opening 444 in the photo sensing region 402. The method for patterning the metal material layer 440 comprises, for example, etching the metal material layer 440 to remove a portion of the metal material layer 440 and exposing a portion of the surface of the upper inter-metal dielectric layer 432c to form the metal conductive line 442 and the opening 444. The opening 444 is disposed on the dielectric layer 432 in the photo sensing region 402, i.e., the bottom surface 444a of the opening 444 is lower than the top surface 442a of the metal conductive line 442 and parallel to the bottom 442b of the metal conductive line 442. Then, a conformal passivation layer 450 is formed on the dielectric layer 432 covering the metal conductive line 442. The conformal passivation layer 450 comprises, for example, a SiO layer, a SiN layer, a SiON layer, or a lamination thereof, and the conformal passivation layer 450 is formed by performing, for example, chemical vapor deposition process.

It should be noted that the conformal passivation layer 450 is deposited depending on the change of the profiles of the metal conductive line 442 and the exposed dielectric layer 432c according to the embodiment. As the conformal passivation layer 450 is thinner than a conventional one, CMP process can be saved. Thus, the incident light path is shortened, and the phenomenon that the incident light cannot be focused on the photo diode is reduced, thereby enhancing the sensitivity of the image sensing device to light and reducing the interference between different elements. Moreover, when the conformal passivation layer 450 comprises a SiN layer or a SiON layer, it has the function of anti-reflection due to the material the same as a anti-reflective coating.

Referring to FIG. 4D, the opening 444 is filled with a color filter 460, i.e., the color filter 460 is disposed in the photo sensing region 402. In the embodiment, the color filter 460 and the metal conductive line 442 have an overlapped portion. Often, there are various color filters in the device to form a color filter array.

It should be noted that the color filter 460 is used to filter the wavelength of the incident light, and should be formed in the photo sensing region 402, i.e., precisely on the photo diode 410. In the embodiment, an opening 444 is formed at the same time when the metal conductive line 442 is formed, and then the color filter 460 is directly disposed in the opening 444. As such, the difficulty in aligning the color filter 460 with the photo diode 410 can be alleviated, thereby improving the process tolerance.

Referring to FIG. 4E, a lens planar layer 470 is formed on the color filter 460 and the exposed conformal passivation layer. The lens planar layer 470 comprises, for example, a transparent polymeric material or other suitable materials. Then, a microlens 480 is formed on the lens planar layer 470 in the photo sensing region 402. The step of fabricating the microlens 480 includes, for example, forming a microlens material layer (not shown) on the lens planar layer 470; patterning the microlens material layer to form a microlens pattern; and then thermally processing the microlens pattern to obtain the microlens 480.

In the embodiment, the conformal passivation layer 450 deposited on the metal conductive line 442 and the exposed dielectric layer 432c is thinner than a conventional one, CMP process can be saved, and thus the manufacture process can be simplified. Moreover, the conformal passivation layer 450 has the function of anti-reflection. Therefore, the incident light path of the photo sensing region is shortened allowing the incident light to precisely enter the photo diode, and thereby enhancing the sensitivity of the image sensing device to light and alleviating the interference between different elements. Furthermore, an opening 444 is formed at the same time when the metal conductive line 442 is formed, and then the color filter 460 is directly disposed in the opening 444. Therefore, the color filter 460 can be precisely formed on the photo diode 410 in the photo sensing region 402. As such, the process tolerance can be improved, and the difficulty in aligning the color filter 460 with the photo diode 410 can be reduced.

Moreover, FIGS. 4F to 4H are schematic sectional views of the flow of the method for fabricating the image sensing device according to another embodiment of the invention which is similar to that of FIGS. 4A and 4B, and description of same components, arrangement and functions thereof will not be repeated herein. The difference between the present embodiment and the foregoing embodiment is described as follows.

Referring to FIG. 4F, the metal material layer 440 is patterned to form a metal conductive line 446 outside the photo sensing region 402, and to form an opening 448 in the photo sensing region 402. The step of patterning the metal material layer 440 comprises, for example, etching the metal material layer 440 to remove a portion of the metal material layer 440 and removing a portion of the dielectric layer 432 in the photo sensing region 402 to form the metal conductive line 446 and the opening 448 respectively. The opening 448 is formed below the dielectric layer 432 within the photo sensing region 402, i.e., the bottom 448a of the opening 448 is lower than the bottom surface 446a of the metal conductive line 446. Then, a conformal passivation layer 452 is formed on the dielectric layer 432 covering the metal conductive line 446. The conformal passivation layer 452 comprises, for example, a SiO layer, a SiN layer, a SiON layer, or a lamination thereof, and may be formed by performing, for example, a chemical vapor deposition process.

The thickness, functions, and advantages of the conformal passivation layer 452 are identical to those described with reference to FIG. 4C, and will not be repeated herein. Furthermore, a portion of the dielectric layer 432 is removed at the same time when the metal conductive line 446 is patterned. Therefore, the dielectric layer 432 within the photo sensing region 402 becomes thin. Accordingly, the dielectric layer 432 and the conformal passivation layer 452 become thin, thereby shortening the incident light path so that the incident light can precisely reach the photo diode 410 and thereby enhancing the sensitivity of the image sensing device to light and alleviating the interference between the lines.

Referring to FIG. 4G, the opening 448 is filled with a color filter 462, i.e., the color filter 462 is disposed in the photo sensing region 402. In the embodiment, the color filter 462 and the metal conductive line 446 may or may not have an overlapped part. The color filters 462 in the device also form an array.

It should be noted that the method of fabricating the color filter 462 in the embodiment is identical to that described with reference to FIG. 4D. Therefore, the difficulty in aligning the color filter 462 with the photo diode 410 can be reduced and the process tolerance is improved.

Referring to FIG. 4H, a lens planar layer 472 is formed on the color filter 462 and the exposed conformal passivation layer 452. Then, a microlens 480 is formed on the lens planar layer 472 in the photo sensing region 402. The method for fabricating the microlens 480 is, for example, identical to that described with FIG. 4E, and will not be repeated herein.

In the image sensing device formed according to the embodiment, the conformal passivation layer 452 is similar to that in FIGS. 4A to 4E and has a thinner thickness than the conventional one. Therefore, the CMP process can be saved and results in the simpler manufacture process. Besides, as the difficulty of aligning the color filter 462 with the photo diode 410 is reduced, the process tolerance is improved. Furthermore, the difference between the present embodiment and the foregoing embodiment is that the dielectric layer 432 within the photo sensing region 402 is thin. Therefore, when the dielectric layer 432 and the conformal passivation layer 452 become thin, the incident light can precisely enter the photo diode 410, thereby enhancing the sensitivity of the image sensing device to light and reducing the interference between different elements.

In view of the above, the present invention at least has the advantages as follows.

1. According to the method of the present invention, a thin conformal passivation layer is formed, so the CMP process can be saved. Besides, the conformal passivation layer has the function of anti-reflection. Therefore, the incident light path can be shortened by easy and simple process.

2. According to the present invention, as the incident light path is shortened, the light can precisely enter the photo diode. Therefore, the sensitivity of the image sensing device to light can be enhanced and the interference between different elements can be alleviated.

3. According to the present invention, the color filter is directly disposed at both sides of the metal conductive line on the top. Therefore, it can be precisely formed on the photo diode in the photo sensing region, thus reducing the difficulty in aligning the color filter with the photo diode, thereby improving the process tolerance.

Though the present invention has been disclosed above by the preferred embodiments, it is not intended to limit the invention. Anybody skilled in the art can make some modifications and variations without departing from the spirit and scope of the invention. Therefore, the protecting range of the invention falls in the appended claims.

What is claimed is:

1. A method for fabricating the image sensing device, comprising:
forming a photo diode in a photo sensing region of a substrate;
forming a transistor electrically connected to the photo diode on a transistor region of the substrate;
forming an interconnect structure on the substrate, wherein the interconnect structure includes a dielectric layer and multiple layers of metal interconnects, and the multiple metal interconnects are disposed in the dielectric layer except the photo sensing region;
forming a metal material layer on the dielectric layer;
patterning the metal material layer to form a metal conductive line outside the photo sensing region and an opening in the photo sensing region;
forming a conformal passivation layer on the dielectric layer for covering the metal conductive line;
filling the opening with a color filter;
forming a lens planar layer on the color filter and the conformal passivation layer; and
forming a microlens on the lens planar layer in the photo sensing region.

2. The method for fabricating the image sensing device according to claim 1, wherein for the step of patterning the metal material layer further comprises removing a portion of the dielectric layer in the photo sensing region.

3. The method for fabricating the image sensing device according to claim 1, wherein the conformal passivation layer comprises SiO layer, SiN layer, SiON layer, or a lamination thereof.

4. The method for fabricating the image sensing device according to claim 1, wherein the step of fabricating the conformal passivation layer comprises performing a chemical vapor deposition process.

5. The method for fabricating the image sensing device according to claim 1, further comprises a step of forming an anti-reflective coating on the substrate and covering the transistor and the photo diode before the step of forming the interconnect structure on the substrate.

6. The method for fabricating the image sensing device according to claim 1, wherein the dielectric layer comprises a lamination having a phosphosilicate glass layer formed by using tetra-ethyl-ortho-silicate as the reactive gas source, an undoped silicate glass layer, a material layer formed by using tetra-ethyl-ortho-silicate as the reactive gas source, and a material layer formed through high density plasma.
